(19) United States
(12) Patent Application Publication
(10) Pub. No.: US 2012/0103519 A1
(43) Pub. Date: May 3, 2012

(54) Plasma Etch Resistant, Highly Oriented Yttria Films, Coated Substrates and Related Methods

(75) Inventors: Mohammed Aheem, (US); Sang-Ho Lee, (US); Thomas Mercer, (US); Vasil Vorsa, (US)

(73) Assignee: Greene, Tweed of Delaware, Inc.

(21) Appl. No.: 13/280,129

(22) Filed: Oct. 24, 2011

Related U.S. Application Data
(60) Provisional application No. 61/406,445, filed on Oct. 25, 2010.

(51) Int. Cl. H01L 21/00; C23C 14/34; C23C 16/48; C23C 4/12; B44C 1/22; B05D 5/00

(52) U.S. Cl. 156/345.3; 427/256; 427/596; 427/448

(57) ABSTRACT

Included within the scope of the invention are plasma etch-resistant films for substrates. The films include a yttria material and a at least a portion of the yttria material is in a crystal phase having an orientation defined by a Miller Index notation {111}. Also included are methods of manufacturing plasma etch-resistant films on a substrate. Such methods include applying a yttria material-containing composition onto at least a portion of a surface of a substrate to form a film. The film includes a yttria material and at least a portion of the yttria material is in a crystal phase having an orientation defined by a Miller Index notation {111}.

### CROSS REFERENCE TO RELATED APPLICATION

This application claims the benefit under 35 U.S.C. §119(e) of U.S. Provisional Patent Application No. 61/406,445, filed Oct. 25, 2019, the entire disclosure of which is incorporated herein by reference.

### BACKGROUND OF THE INVENTION

Resistance to plasmas is a desirable property for components used in processing chambers where corrosive environments are present. Process chambers and component apparatus present within or used in conjunction with processing chambers which are used in the fabrication of electronic devices and MEMS are frequently constructed from various substrates such as sapphire, silica, fused silica, quartz, fused quartz, alumina, sapphire, silicon, aluminum, anodized aluminum, zirconium oxide, and an aluminum alloy, as these materials are known to have a level of plasma resistance.

These materials, however, may be easily eroded during routine processing conditions whether chemically, physically, and/or thermally. Typically, the most severe environments are presented to the substrates during plasma etch processes, whether as part of etch processing or chamber cleaning. To ameliorate the erosion or degradation of the substrates, attempts have been made to protect and preserve them by application of shielding or film layers. The aim of such shielding or film layers is to act to reduce exposure to various plasmas (NF₃, Cl₂, CHF₃, CH₂F₂, SF₆ and HBr) and thereby prevent or reduce weight loss and/or to reduce particulation during dry etching processes where particles may be dislodged from the chamber walls and various components inside the processing chamber.

Conventional films and methods have been used in an attempt to develop a suitably shielding or protective layer. For example, films that contain various ceramic materials such as alumina, aluminum nitride, and zirconia that are known to be chemically stable in plasma etching conditions have been prepared. Although these films often exhibit improved plasma resistance in the form of reduced weight loss, they still frequently generate unwanted particulates. Particulates liberated in the processing chamber result in damaged or flawed wafers, which must then be discarded, greatly increasing the cost of production and reducing production line efficiency.

As an example, alumina-coated silica or alumina-coated quartz are known to exhibit a reduced etch rate, as compared to bare silica or quartz. However, in a fluoride-containing etch environment, one finds that alumina from the film is oxidized, forming aluminum fluoride, a highly stable and non-volatile compound that builds on chamber walls. Subsequently, the aluminum fluoride particulates shed off the chamber walls and contaminate the wafers.

Several prior attempts have been made to reduce particulation by coating quartz substrates with yttria. These attempts have mostly been with very thick (typically >50 micron) thermal-spray yttria. Thermal-sprayed yttria films, however, are porous and generate unwanted particulates.

There remains a need in the art for a film that can be applied to substrates that is resistant to degradation upon exposure to plasma and exhibits reduced particulation.

### BRIEF SUMMARY OF THE INVENTION

Included within the scope of the invention are plasma etch-resistant films for substrates. The films include a yttria material and a at least a portion of the yttria material is in a crystal phase having an orientation defined by a Miller Index notation {111}. Also included are methods of manufacturing plasma etch-resistant films on a substrate. Such methods include applying a yttria material-containing composition onto at least a portion of a surface of a substrate to form a film. The film includes a yttria material and at least a portion of the yttria material is in a crystal phase having an orientation defined by a Miller Index notation {111}.

Contemplated with the scope of the invention are semiconductor processing apparatus components that include a substrate and a plasma etch-resistant film. The film includes a yttria material and at least a portion of the yttria material is in a crystal phase having an orientation defined by a Miller Index notation {111} or have crystal planes that are substantially parallel to the surface of the substrate.

Methods of increasing the plasma resistance of substrate are also included. These methods include depositing a yttria material-containing composition onto at least a portion of a surface of a substrate to form a film. The film comprises a yttria material and at least a portion of the yttria material is in a crystal phase having an orientation defined by a Miller Index notation {111}. The portion of the substrate bearing the film exhibits an increased resistance to degradation upon exposure to plasma.

### BRIEF DESCRIPTION OF THE SEVERAL VIEWS OF THE DRAWINGS

The foregoing summary, as well as the following detailed description of embodiments of the invention, may be better understood when read in conjunction with the appended drawings. However, it should be understood, that the invention is not limited to the precise arrangements and instrumentalities shown. In the drawings:

FIG. 1 is a schematic representation of a polycrystalline film consisting of a randomly oriented grain structure (top) and polycrystalline film with the orientation of the invention (bottom);

FIG. 2 is an X-ray diffraction spectra of electron-beam deposited yttrium oxide films on fused quartz showing a film having a crystal orientation defined by Miller Index notation {111} and a film having an orientation defined by Miller Index notation {100};

FIG. 3A is an optical photograph of an yttrium oxide film with a crystal orientation defined by Miller Index notation {111} on fused quartz after the film was subjected to NF₃+O₂ plasmas for 4 hours;

FIG. 3B is an optical photograph of an yttrium oxide film with a crystal orientation defined by Miller Index notation [100] on fused quartz after the film was subjected to NF₃+O₂ plasmas for 4 hours. Significant etching can seen;

FIG. 4A is an optical microscope image (100×) of an yttrium oxide film with a crystal orientation defined by Miller Index notation {111} on fused quartz prior to any exposure to plasmas;

FIG. 4B is an optical microscope image (100×) of an yttrium oxide film with a crystal orientation defined by Miller Index notation {111} on fused quartz after the film was subjected to NF₃+O₂ plasmas for 4 hours;

FIG. 5A is an optical microscope image (100×) of an yttrium oxide film with a crystal orientation defined by Miller Index notation {100} on fused quartz prior to any exposure to plasmas;

FIG. 5B is an optical microscope image (100×) of an yttrium oxide film with a crystal orientation defined by Miller Index notation {100} on fused quartz after the film was subjected to NF₃+O₂ plasmas for 4 hours;

FIG. 6A is a scanning electron micrograph of a portion of a film of the invention showing cracks and fissures in its surface;

FIG. 6B is scanning electron micrograph of the substantially identical portion of the film shown in FIG. 6A after exposure to a fluorine-containing environment for 2 hours;

FIG. 7A is scanning electron micrograph of a portion of a film of the invention showing cracks and fissures in its surface; and

FIG. 7B is scanning electron micrograph of the substantially identical portion of the film shown in FIG. 7A after exposure to a fluorine-containing environment for 2 hours.

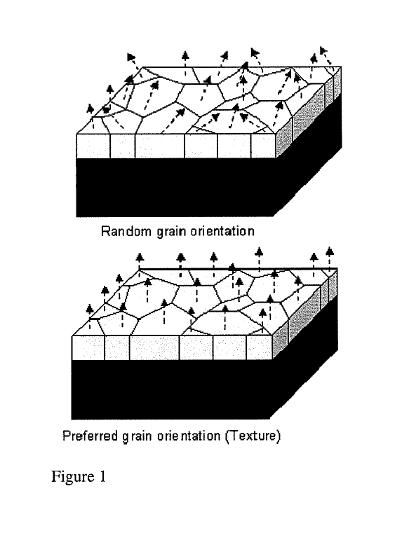

### DETAILED DESCRIPTION OF THE INVENTION

It has been found that that by forming a film having the crystallographic texture described herein, the film's resistance to degradation upon exposure to gas plasma is improved as are several other desirable properties. The invention includes a plasma etch-resistant film for use on various substrates; methods of preparing the film (and the film and the substrate combination); various substrates; including those forming portions of semiconductor processing apparatus components, bearing the film and methods of increasing the plasma resistance by deposition or application of the films of the invention to a substrate. In some embodiments, if the film exhibits one or more desirable properties, including reduced rate of plasma etching (under exposure to corrosive chemicals or plasmas), reduced particulation during use in a semiconductor process, and/or the ability to self-repair cracks, fissures and other degradation under exposure to gas plasmas, such as those containing fluorine.

The invention includes a plasma etch-resistant film for use on various substrates. By “improved plasma resistance”, it is meant that the film of the invention, upon exposure to corrosive chemicals, such as gas plasmas (and particularly fluorine plasmas) is less degraded than is a conventional yttria film. Degradation of the films may be evaluated using any means commonly accepted in the art including visual means such as optical or scanning electron microscopy, wherein areas of cracks, fissures, and undercutting are assessed; by evaluation of the adhesion of the film to the substrate, where greater adhesion corresponds to less degradation or by spectral reflectance.

The film is formed by deposition or application of yttria material onto a substrate. The yttria material may be any yttria-containing or yttria-derived material that exhibits a level of plasma resistance and/or reduced particulation when exposed to a plasma containing environment, particularly, for example an environment containing a fluorine-based plasma. Exemplary yttria materials include without limitation yttria, yttrium aluminum garnet, yttrium aluminum perovskite, yttria containing one or more dopant or other additives, or combinations of these materials.

The film is deposited on the substrate such that at least a portion of the yttria material is present in a highly oriented crystallographic texture. Yttria may exist in a polycrystalline form and such crystals are commonly understood to have a structure represented by a cube. As in known in the art, the orientation of the specific planes of a cubic crystal are represented by a mathematical description referred to as the Miller Indices (or may be described using “Miller Index notation”). The Miller Indices are a notation system to express planes and directions in crystal lattices, such as those formed by yttria and yttria materials. In the crystal lattices, a family of lattice planes is determined by three integers l, m, and n, (these are collectively the Miller indices). Conventional notation writes these Miller indices as “(hkl)”. Each index denotes a plane orthogonal to a direction (h, k, l) in the basis of the reciprocal lattice vectors. By convention, negative integers are written with a bar, as in 3 for −3. The integers are usually written in lowest terms, i.e., their greatest common divisor should be 1. For example, in simple cubic crystals, Miller index (100) represents a plane orthogonal to direction l; index (010) represents a plane orthogonal to direction m, and index (001) represents a plane orthogonal to n. When the Miller indices are notated using the bracket symbol “{hkl}”, the set of all directions that are equivalent to [lmn] by symmetry is denoted.

In the film of the invention, the crystals present predominantly have an orientation described as {111} using Miller index notation. It is preferred that the yttria material in the film exists predominantly in the {111} orientation. For clarity, by having an {111} orientation it is meant that the planes of the crystals are orientated to as to be substantially parallel to the surface of the film.

It is not necessary that all the film's yttria material is present in the {111} orientation, only that a portion is oriented {111}. Some material may be present in alternative crystal orientations and/or may be amorphous (both circumstances collectively referred herein as “non-parallel orientation”). Specifically, in some conditions, it may be preferred to that about 50%, about 60%, about 70%, about 80%, about 90%, about 95%, about 98% or about 99% or more or more of the yttria material is in a crystal phase having an orientation defined by a Miller Index notation {111}.

In some embodiments, it may be preferred that the portion of the yttria material having a non-parallel orientation (or a fraction of that portion) has the alterative orientation described by the Miller Index notation {101}.

The film may have any average crystallite size or grain size and the grain size may vary as a function of the thickness of the film. However, in some embodiments, it may be preferred that the average crystal size of the crystallites that are present in the film have about 100 Å to about 600 Å or about 225 Å to about 350 Å, as measured by X-ray diffraction.

The film may be any thickness desired and be continuously applied along the surface of the substrate or discontinuously applied (that is, the film may be present on only a portion or portions of the substrate). Thickness and continuity of the film will necessarily vary depending on the contemplated end application for the film-coated substrate. In some embodiments, it may be preferable that the film has a thickness of about 0.1 to about 30 microns, about 0.5 to about 10 microns, about 5 microns to about 20 microns, and/or about 10 microns to about 17 microns.

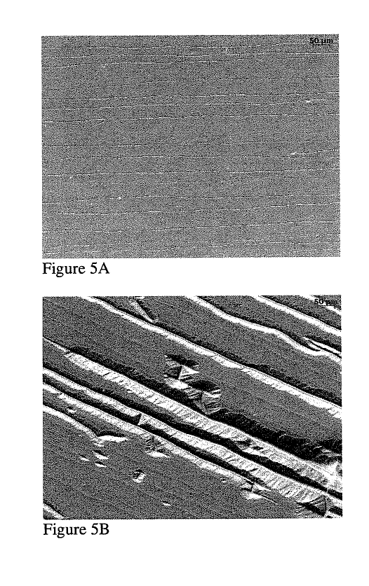

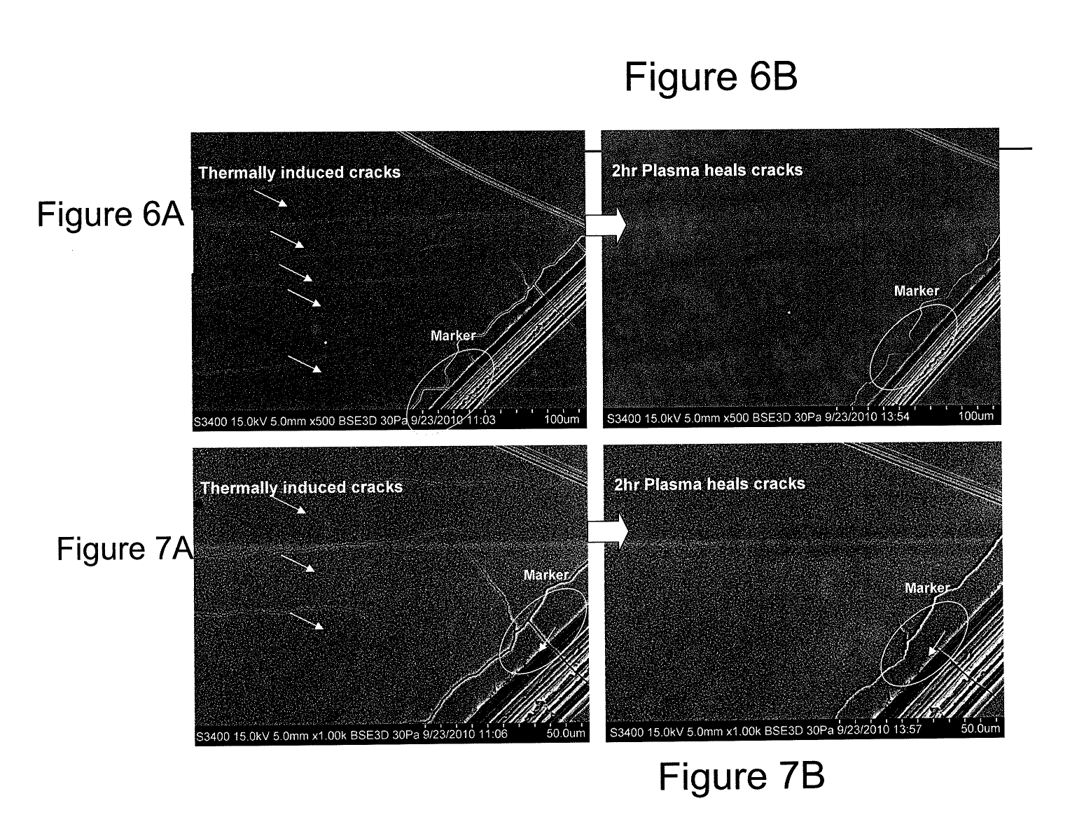

In addition to exhibiting a reduced rate of etching and reduced particulation during use in a semiconductor process as described above, the film is capable of self repair under specific conditions, including under exposure to fluorine gas plasma, such as those used in semiconductor processing. FIGS. 6A and 7A each are micrographs of an yttrium oxide film of the invention on a quartz substrate. In each micrograph numerous thermally-induced cracks and fissures on the surfaces of the films are plainly visible, in proximity to the marker (designated).

FIGS. 6B and 7B are micrographs of the substantially identical location on each of the film surfaces shown in FIG. 6A and 6B respectively (note the location of the marker) after each film was subjected to a fluorine gas plasma-containing environment for 2 hours. The micrographs clearly show that the cracks and fissures visible prior to the films' exposure to a fluorine gas plasma-containing environment have repaired or, in some cases, have completely disappeared.

The substrates to which the films of the invention are applied may be any known in the art, particularly those used in semiconductor processing. In some circumstances, it may be preferable that the substrate is a material that, independent of the film, has one or more high performance properties, such as resistance to corrosive chemicals, resistance to high temperatures and/or pressures, resistance to gas plasmas, mechanical strength, hardness, etc. Exemplary substrates may include polymers, metals, silica, fused quartz, quartz, alumina, sapphire, silicon, aluminum, anodized aluminum, and or zirconium oxide.

In some embodiments, the substrate is a semiconductor processing apparatus component or a portion of a semiconductor processing apparatus component. Such components include any known or developed in the art. Exemplary components may include, without limitation, a chamber wall, a chamber floor, a screw, a wafer boat or other tool or device used to position the wafer(s), a fastener, a window, a dispersion disc, a shower head, a focus ring, an inner ring, an outer ring, a capture ring, an insert ring, a gas transfer tube, and a heater block.

Methods of manufacturing a plasma etch-resistant film on a substrate are also included within the scope of the invention. Such methods include depositing or applying a yttria material-containing composition onto at least a portion of a surface of a substrate to form the film described above. The composition applied or deposited may be substantially pure yttria material or it may be yttria material combined with other coating materials. Depending on the application or deposition methods used, a carrier (gas or liquid) may be included.

The film may be deposited using any suitable methods known or developed in the art. Exemplary methods may include, without limitation, aerosol deposition, electron beam evaporation, sputtering, plasma spraying, atomic layer deposition (ALD), and chemical vapor deposition (CVD).

The specific parameters under which the film is applied/deposited may vary depending on the method of application or deposition used, although such minor variations within the ordinary skill of one in the art familiar with such processes.

An example of a deposition process using a quartz substrate and an electron beam process may include: precleaning of the bare substrate using a solvent, such as, for example, an organic solvent like isopropyl alcohol and pre heating of the electron beam chamber to a target temperature in range of about 25° C. to about 600° C. Typically the time necessary to achieve preheating of the substrate is about 1 to about 5 hours, depending on the substrate mass; optional in situ precleaning of substrate using an ion beam. If this precleaning step is undertaken, the gases used may be argon (most typical), oxygen, oxygen/argon blend, or other noble gases such as xenon. An exemplary process may use granular Y₂O₃ having a high purity, such as 90% or greater, preferable 98% or greater purity. The Y₂O₃ is premelted in a single step or in multiple steps prior to deposition and may be deposited onto the substrate at a rate of about 1 to about 10 micrometers per hour. During deposition, oxygen gas may be introduced into the chamber in a partial pressure range of about 5×10⁻⁶ to 1×10⁻³ torr. In some circumstances, gas introduction may result in improved film quality.

In some embodiments, ion beam assisted deposition (IBAD) may be used to carryout the deposition. Typically, gases used in IBAD include: argon (most typical), oxygen, oxygen/argon blend, or other noble gases such as xenon. An exemplary process is described in, for example, Park, S. and Morton, D. P. (2006) Ion beam assisted texturing of polycrystalline Y₂O₃ films deposited via electron beam evaporation”, Thin Solid Films 510: 142-147.

After deposition, film-coated substrate is cooled back to room temperature in a controlled manner, for example at a rate of about 10° C. to about 200° C. per hour.

Regardless of the processes selected, it may be desirable that the yttria material is applied to the substrate to form a film when the substrate is about room temperature (21° C.) to about 500° C., about 100° C. to about 500° C., and/or about 400° C. to about 500° C.

In any of the process described herein the yttria material may be deposited or applied directly on to the surface of the substrate (that is, the film is formed directly against the surface of the substrate). Alternatively, the substrate may be coated with other materials (forming one or more intervening layers of films) prior to the deposition of the yttria material. In addition or alternatively, the film of the invention, once formed, may be coated with additional layer(s), for example an extra sacrificial layer of alumina, to further enhance overall plasma resistance.

Also contemplated within the scope of the invention are methods of increasing the plasma resistance of substrate comprising depositing a yttria material-containing composition on to at least a portion of a surface of a substrate to form a film as described above. The portion of the substrate bearing the film exhibits an increased resistance to degradation upon exposure to plasma and/or generates a reduced quantity of contaminating particulates, as compared to the identical substrate bearing an yttria film that is formed of a yttria material that is not oriented in the crystal microstructure described above.

### Example I

Two sets of yttrium oxide films were grown on fused quartz coupons (dimensions: 1 inch×1 inch; ⅛ inch thick) by electron beam evaporation. Each coupon was installed in the electron beam film chamber and the chamber was vacuum purged overnight. The film chamber vacuum level was maintained at 2.4×10⁻⁵ ton and preheated for 12 hours to ensure temperature equilibrium was reached.

High purity (>99.99%) Y₂O₃ target was evaporated by electron beam and each coupon was coated for 4 hours to reach target thickness of about 4 microns. During the film process, temperature of the substrate was maintained between about 150° C. to about 350° C.

One set of films was grown to predominantly produce a crystalline structure having an orientation described by Miller Index notation {100}. The second set was grown to produce predominantly a crystalline structure having an orientation described by Miller Index notation {111}.

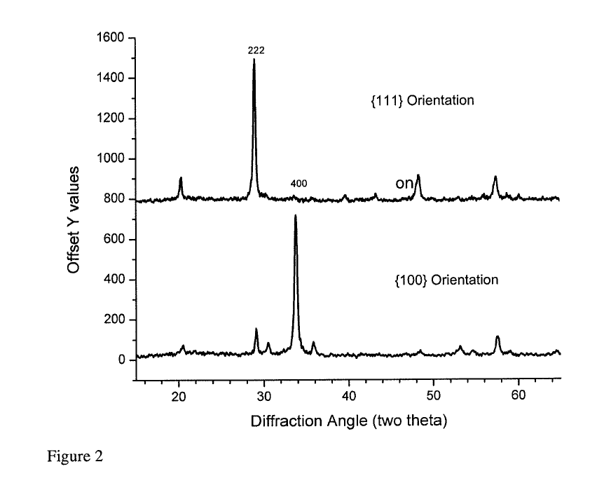

FIG. 2 shows x-ray diffraction (XRD) measurements of the two films. It was found that {111} oriented films exhibited improved plasma resistance (e.g., resistant to degradation by plasma) as compared to the films grown with a predominant {100} orientation.

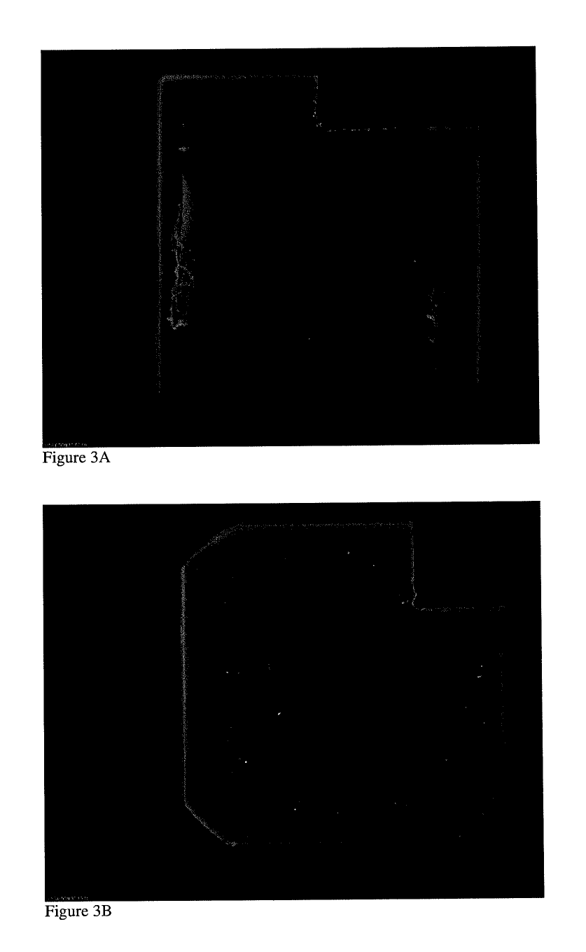

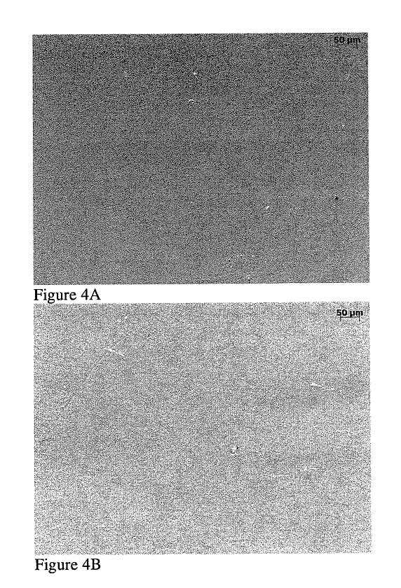

FIGS. 2A and 2B show the result of {111} and {100} oriented films following 4 hours of NF₃/O₂ plasma etch. FIG. 3A shows that the integrity of the {111} oriented film is much greater than the {100} oriented film shown in FIG. 3B. The film in 3A shows some delamination at film edges where the film boundary is. However, the center of the film in FIG. 3A is intact whereas the film in FIG. 3B shows plasma attack of the film as manifested by the horizontal lines seen in the figure. FIG. 4A and 4B show microscope images of the {111} film shown in FIG. 3A taken at a magnification of 100 times.

FIG. 4A shows the {111} oriented film prior to exposing it to 4 hours of NF₃/O₂ plasma etch. FIG. 4B shows the same film following 4 hours of exposure to plasma etch. As can be seen from FIG. 4B there is no significant change in the film.

FIGS. 5A and 5B show the {100} oriented film before and after 4 hours exposure to plasma etch, respectively. It is apparent from the figures that the {100} oriented film did not withstand the plasma environment as well as the {111} oriented film. Indeed, the {100} oriented film performed so poorly that the substrate under the film layer was exposed to the plasma, leading to the undercutting of the substrate and eventual delamination of the film.

Moreover, the {111} oriented film exhibits a reduced etch rate, as compared to the {100} oriented film.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A plasma etch-resistant film for a substrate comprising a yttria material wherein at least a portion of the yttria material is in a crystal phase having an orientation defined by a Miller Index notation {111}.

2. The film of claim 1, wherein 50% or more of the yttria material is in a crystal phase having an orientation defined by a Miller Index notation {111}.

3. The film of claim 1, wherein 90% or more of the yttria material is in a crystal phase having an orientation defined by a Miller Index notation {111}.

4. The film of claim 1, wherein 95% or more of the yttria material is in a crystal phase having an orientation defined by a Miller Index notation {111}.

5. The film of claim 1, wherein 98% or more or more of the yttria material is in a crystal phase having an orientation defined by a Miller Index notation {111}.

6. The film of claim 1, wherein the substrate is chosen from silica, fused silica, quartz, fused quartz, alumina, sapphire, silicon, aluminum, anodized aluminum, zirconium oxide, and aluminum alloy.

7. The film of claim 6, wherein the substrate is a semiconductor processing apparatus component.

8. The film of claim 7, wherein semiconductor processing apparatus component is selected from a chamber wall, a chamber floor, a screw, a wafer boat, a fastener, a window, a dispersion disc, a shower head, a focus ring, an inner ring, an outer ring, a capture ring, an insert ring, a gas transfer tube, and a heater block.

9. The film of claim 1, wherein the film has a thickness of about 0.5 microns to about 30 microns.

10. The film of claim 1, wherein the film has a thickness of about 5 microns to about 20 microns.

11. The film of claim 1, wherein the film has a thickness of about 10 microns to about 17 microns.

12. The film of claim 1, wherein the yttria material is yttria.

13. The film of claim 1, wherein the yttria material is a yttria-derived composite.

14. The film of claim 13, wherein the yttria-derived composite is selected from yttrium aluminum garnet and yttrium aluminum perovskite.

15. The film of claim 1, wherein the film is formed using a process selected from electron beam vapor deposition, electron beam evaporation, sputtering, plasma spraying, atomic layer deposition, and chemical vapor deposition (CVD).

16. The film of claim 15, wherein the process is carried out when the substrate has a temperature of about 21° C. to about 500° C.

17. The film of claim 15, wherein the process is carried out when the substrate has a temperature of about 100° C. to about 500° C.

18. The film of claim 15, wherein the process is carried out when the substrate has a temperature of about 400° C. to about 500° C.

19. The film of claim 1, wherein upon exposure to a fluorine-containing environment, a crack or a fissure present in the film is self-repaired.

20. A method of manufacturing a plasma etch-resistant film on a substrate comprising depositing a yttria material-containing composition onto at least a portion of a surface of a substrate to form a film, wherein the film comprises a yttria material and at least a portion of the yttria material is in a crystal phase having an orientation defined by a Miller Index notation {111}.

21. The method of claim 20, wherein the yttria material is deposited using a process selected from electron beam vapor deposition, electron beam evaporation, sputtering, plasma spraying, atomic layer deposition, and chemical vapor deposition (CVD).

22. The method of claim 21, wherein the process is carried out when the substrate has a temperature of about 21° C. to about 500° C.

23. The method of claim 21, wherein the process is carried out when the substrate has a temperature of about 100° C. to about 500° C.

24. The method of claim 21, wherein the process is carried out when the substrate has a temperature of about 400° C. to about 500° C.

25. The method of claim 20, wherein 50% or more of the yttria material is in a crystal phase having an orientation defined by a Miller Index notation {111}.

26. The method of claim 20, wherein 90% or more of the yttria material is in a crystal phase having an orientation defined by a Miller Index notation {111}.

27. The method of claim 20, wherein 95% or more of the yttria material is in a crystal phase having an orientation defined by a Miller Index notation {111}.

28. The method of claim 20, wherein 98% or more or more of the yttria material is in a crystal phase having an orientation defined by a Miller Index notation {111}.

29. The method of claim 20, wherein the substrate is chosen from silica, fused silica, quartz, fused quartz, alumina, sapphire, silicon, aluminum, anodized aluminum, zirconium oxide, and an aluminum alloy.

30. The method of claim 20, wherein the yttria material is yttria.

31. The method of claim 20, wherein the yttria material is a yttria-derived composite.

32. The method of claim 31, wherein the yttria-derived composite is selected from yttrium aluminum garnet and yttrium aluminum perovskite.

33. The method of claim 20, wherein the film has a thickness of about 0.5 microns to about 30 microns.

34. The method of claim 20, wherein the film has a thickness of about 5 microns to about 20 microns.

35. The method of claim 20, wherein the film has a thickness of about 10 microns to about 17 microns.

36. A semiconductor processing apparatus component comprising a substrate and a plasma etch-resistant film comprising a yttria material wherein at least a portion of the yttria material is in a crystal phase having an orientation defined by a Miller Index notation {111}.

37. The component of claim 36, wherein 50% or more of the yttria material is in a crystal phase having an orientation defined by a Miller Index notation {111}.

38. The component of claim 36, wherein 90% or more of the yttria material is in a crystal phase having an orientation defined by a Miller Index notation {111}.

39. The component of claim 36, wherein 95% or more of the yttria material is in a crystal phase having an orientation defined by a Miller Index notation {111}.

40. The component of claim 36, wherein 98% or more or more of the yttria material is in a crystal phase having an orientation defined by a Miller Index notation {111}.

41. The component of claim 36, wherein the substrate is chosen from silica, fused silica, quartz, fused quartz, alumina, sapphire, silicon, aluminum, anodized aluminum, zirconium oxide, and an aluminum alloy.

42. The component of claim 36, wherein the film has a thickness of about 0.5 microns to about 30 microns.

43. The component of claim 36, wherein the film has a thickness of about 5 microns to about 20 microns.

44. The component of claim 36, wherein the film has a thickness of about 10 microns to about 17 microns.

45. The component of claim 36, wherein the yttria material is yttria.

46. The component of claim 36, wherein the yttria material is a yttria-derived composite.

47. The component of claim 46, wherein the yttria-derived composite is selected from yttrium aluminum garnet and yttrium aluminum perovskite.

48. The component of claim 36, wherein the film is formed using a process selected from electron beam vapor deposition, electron beam evaporation, sputtering, plasma spraying, atomic layer deposition, and chemical vapor deposition (CVD).

49. The component of claim 48, wherein the process is carried out when the substrate has a temperature of about 21° C. to about 500° C.

50. The component of claim 48, wherein the process is carried out when the substrate has a temperature of about 100° C. to about 500° C.

51. The component of claim 48, wherein the process is carried out when the substrate has a temperature of about 400° C. to about 500° C.

52. The component of claim 36, wherein upon exposure to a fluorine-containing environment, a crack or a fissure present in the film is self-repaired.

53. The component of claim 36, wherein the component is one of a chamber wall, a chamber floor, a screw, a wafer boat, a fastener, a window, a dispersion disc, a shower head, a focus ring, an inner ring, an outer ring, a capture ring, an insert ring, a gas transfer tube, and a heater block.

54. A method of increasing the plasma resistance of substrate comprising depositing an yttria material-containing composition on to at least a portion of a surface of a substrate to form a film, wherein the film wherein the film comprises a yttria material and at least a portion of the yttria material is in a crystal phase having an orientation defined by a Miller Index notation {111} and wherein the portion of the substrate bearing the film exhibits an increased resistance to degradation upon exposure to plasma.

55. The method of claim 54, wherein 50% or more of the yttria material is in a crystal phase having an orientation defined by a Miller Index notation {111}.

56. The method of claim 54, wherein 90% or more of the yttria material is in a crystal phase having an orientation defined by a Miller Index notation {111}.

57. The method of claim 54, wherein 95% or more of the yttria material is in a crystal phase having an orientation defined by a Miller Index notation {111}.

58. The method of claim 54, wherein 98% or more or more of the yttria material is in a crystal phase having an orientation defined by a Miller Index notation {111}.

59. The method of claim 54, wherein the substrate is chosen from silica, fused silica, quartz, fused quartz, alumina, sapphire, silicon, aluminum, anodized aluminum, zirconium oxide, and an aluminum alloy.

60. The method of claim 54, wherein the film has a thickness of about 0.5 microns to about 30 microns.

61. The method of claim 54, wherein the film has a thickness of about 5 microns to about 20 microns.

62. The method of claim 54, wherein the film has a thickness of about 10 microns to about 17 microns.

63. The method of claim 54, wherein the yttria material is yttria.

64. The method of claim 54, wherein the yttria material is a yttria-derived composite.

65. The method of claim 64, wherein the yttria-derived composite is selected from yttrium aluminum garnet and yttrium aluminum perovskite.

66. The method of claim 54, wherein the film is formed using a process selected from electron beam vapor deposition, electron beam evaporation, sputtering, plasma spraying, atomic layer deposition, and chemical vapor deposition (CVD).

67. The method of claim 66, wherein the process is carried out when the substrate has a temperature of about 21° C. to about 500° C.

68. The method of claim 66, wherein the process is carried out when the substrate has a temperature of about 100° C. to about 500° C.

69. The method of claim 66, wherein the process is carried out when the substrate has a temperature of about 400° C. to about 500° C.

70. The method of claim 54, wherein upon exposure to a fluorine-containing environment, a crack or a fissure present in the film is self-repaired.

71. The method of claim 54, wherein the component is one of a chamber wall, a chamber floor, a screw, a wafer boat, a fastener, a window, a dispersion disc, a shower head, a focus ring, an inner ring, an outer ring, a capture ring, an insert ring, a gas transfer tube, and a heater block.

72. A plasma etch-resistant film for a substrate comprising a yttria material wherein at least a portion of the yttria material is in a crystal phase having an orientation such that the planes of the crystal are oriented so as to be substantially parallel to the surface of the substrate.

73. A method of manufacturing a plasma etch-resistant film on a substrate comprising depositing a yttria material-containing composition onto at least a portion of a surface of a substrate to form a film, wherein the film comprises a yttria material and at least a portion of the yttria material is in a crystal phase an orientation such that the planes of the crystal are oriented so as to be substantially parallel to the surface of the substrate.

74. A semiconductor processing apparatus component comprising a substrate and a plasma etch-resistant film comprising a yttria material wherein at least a portion of the yttria material is in a crystal phase an orientation such that the planes of the crystal are oriented so as to be substantially parallel to the surface of the substrate.

75. A method of increasing the plasma resistance of substrate comprising depositing an yttria material-containing composition on to at least a portion of a surface of a substrate to form a film, wherein the film wherein the film comprises a yttria material and at least a portion of the yttria material is in a crystal phase an orientation such that the planes of the crystal are oriented so as to be substantially parallel to the surface of the substrate and wherein the portion of the substrate bearing the film exhibits an increased resistance to degradation upon exposure to plasma.
